(19) United States
(12) Patent Application Publication
(10) Pub. No.: US 2025/0203895 A1
(43) Pub. Date: Jun. 19, 2025

(54) TRENCH GATE TYPE IGBT AND DRIVING METHOD THEREOF

(71) Applicant: WILL SEMICONDUCTOR (SHANGHAI) CO. LTD., SHANGHAI (CN)

(72) Inventors: TETSUYA OKADA, YOKOHAMA-SHI (JP); TOSHIYUKI NAKA, YOKOHAMA-SHI (JP)

(21) Appl. No.: 18/590,429

(22) Filed: Feb. 28, 2024

(30) Foreign Application Priority Data
Dec. 13, 2023 (JP) 2023-210650

(51) Int. Cl. H01L 29/739; H01L 29/10; H01L 29/66; H03K 17/567

(52) U.S. Cl. CPC H10D 12/481; H03K 17/567; H10D 12/038; H10D 62/393

(57) ABSTRACT

[Problem to be solved] The disclosure is to have an appropriate short circuit withstand capacity and reduce turn-off loss and conduction loss.

[Solution] A trench gate type IGBT includes: a semiconductor substrate; and a plurality of trench-type gates, extending from the front surface of the semiconductor substrate to the back surface side and controlling a current flowing, by application of a voltage, to a channel region formed in the periphery. The trench gate type IGBT controls a current between an emitter and a collector by the voltage applied to the trench-type gates. The plurality of trench-type gates include: one or more main gates, which have a relatively long ON time; and one or more control gates, which have a relatively short ON time, are turned on after the main gates are turned on, and are turned off before the main gates are turned off.

### BACKGROUND OF THE INVENTION

### 1. Field of the Invention

Conventionally, insulated gate bipolar transistors (IGBTs) have been widely used as a switching element of a circuit that drives a high-power motor.

For example, Patent document 1 indicates that in a trench gate type IGBT, a carrier store (CS) layer that accumulates carriers (for example, holes) is arranged on the lower side of a channel of the IGBT.

### PRIOR ART DOCUMENTS

### Patent Documents

[Patent document 1] Japanese Patent Laid-Open No. 2005-347289

### SUMMARY OF THE INVENTION

### Problems to be Solved

Here, in a case where the carrier store layer is arranged, the voltage drop (collector-emitter voltage Vce) when the IGBT is on can be reduced. That is, the voltage drop due to the on-resistance of the IGBT can be reduced, and then the energy loss during the on-time can be reduced. However, if carriers are excessively accumulated in the carrier store layer, the saturation current will increase and the short circuit withstand capacity will deteriorate. In addition, when the IGBT is turned off (switched from ON to OFF), the time required for turn-off becomes longer and the energy consumption (loss during turn-off) increases due to the influence of remaining carriers.

### Means to Solve Problems

A trench gate type IGBT related to the disclosure includes:
a semiconductor substrate; and
a plurality of trench-type gates, extending from the front surface of the semiconductor substrate to the back surface side and controlling a current flowing, by application of a voltage, to a channel region formed in the periphery; the trench gate type IGBT controlling a current between an emitter and a collector by the voltage applied to the trench-type gates; where
the plurality of trench-type gates include:
one or more main gates, which have a relatively long ON time; and
one or more control gates, which have a relatively short ON time, are turned on after the main gates are turned on, and are turned off before the main gates are turned off.

### Effects

According to the trench gate type IGBT related to the disclosure, because the control gate is turned on after the main gate is turned on, there is a time during which only the main gate is on. Because the saturation current when only the main gate is on can be reduced, the short circuit withstand capacity can be maintained at a predetermined value even if the concentration of the carrier store layer is increased. In addition, by turning off the main gate after the control gate is turned off, carriers can be reduced when only the main gate is on, and the loss during turn-off can be reduced. Furthermore, by increasing the concentration of the carrier store layer, the voltage drop when the IGBT is on can also be reduced. However, from the viewpoint of the short circuit withstand capacity and the withstand voltage, it is desirable that the impurity concentration of the carrier store layer is 3E¹⁷ to 2E¹⁸ (atoms/cm²).

### BRIEF DESCRIPTION OF THE DRAWINGS

FIG. 1 is a cross-sectional view schematically showing a configuration of a trench gate type IGBT according to an embodiment.

FIG. 2 is a diagram showing states of the collector-emitter voltage Vce, the collector current Ic, the voltage Vmg of a main gate 120MG, and the voltage Vog of a control gate 120CG of the IGBT.

FIG. 3 is a diagram showing the relationship between the carrier addition amount (atoms/cm²) of a carrier store (CS) layer and the saturation current Isat (A/cm²).

FIG. 4 is a diagram showing the relationship between the carrier addition amount (atoms/cm²) of the carrier store (CS) layer and the collector-emitter saturation voltage Vce(sat) (V).

FIG. 5 is a diagram showing the relationship between the carrier addition amount (atoms/cm²) of the carrier store (CS) layer and the loss during turn-off (mJ).

FIG. 6 is a diagram showing the relationship between the collector-emitter saturation voltage (Vce(sat)) and the collector current Ic.

FIG. 7 is a plan view showing an example of a metal wiring layer (single-layer) of the IGBT, the IGBT having a square planar shape in this example.

FIG. 8A is an enlarged schematic diagram of part A in FIG. 7.

FIG. 8B is a cross-sectional view taken along line A-A′ of FIG. 8A.

FIG. 8C is a cross-sectional view taken along line B-B′ of FIG. 8A.

FIG. 9 is a plan view showing another example of the metal wiring layer (single-layer) of the IGBT.

FIG. 10 is an enlarged schematic diagram of part B of FIG. 9.

FIG. 11 is a plan view showing an example of the metal wiring layer (two-layer) of the IGBT.

FIG. 12A is an enlarged schematic diagram of part C of FIG. 11.

FIG. 12B is a cross-sectional view taken along line A-A′ of FIG. 12A.

FIG. 13 is a cross-sectional view schematically showing another configuration of the trench gate type IGBT according to the embodiment.

FIG. 14 is a diagram showing an example of a control unit.

FIG. 15 is a timing chart showing operations of the control unit.

FIG. 16 is a diagram showing a manufacturing process of the IGBT according to the embodiment.

### PREFERRED EMBODIMENT OF THE PRESENT INVENTION

Hereinafter, embodiments of the disclosure are described with reference to the drawings. Note that, the following embodiments do not limit the scope of the disclosure, and configurations obtained by selectively combining multiple examples are also included in the disclosure.

### “Configuration of IGBT”

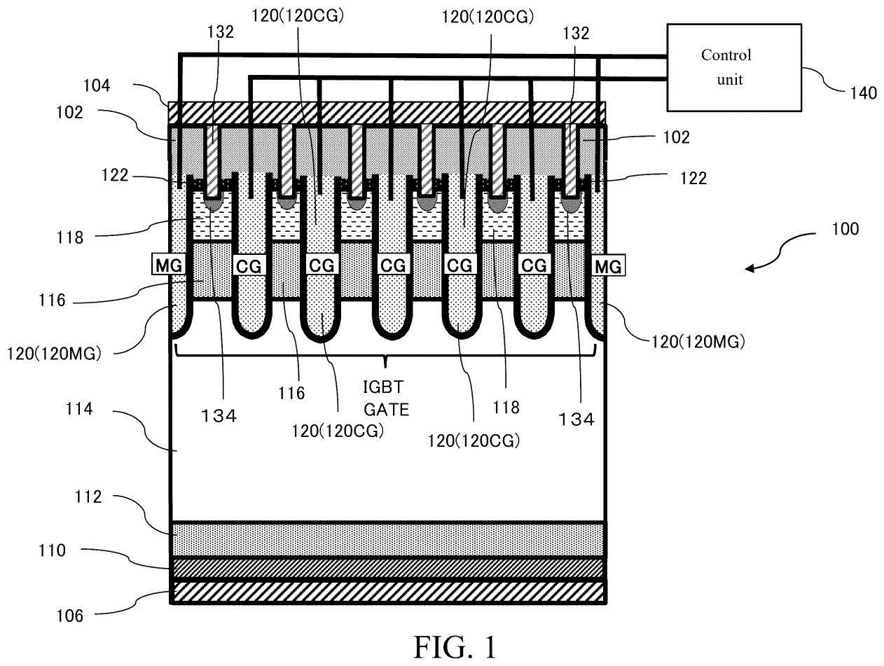

FIG. 1 is a cross-sectional view schematically showing a configuration of a trench gate type IGBT according to an embodiment.

An interlayer insulating film 102 is formed on the front surface of a semiconductor substrate 100. On the interlayer insulating film 102, a metal wiring layer is arranged, and necessary electrical connections are made. In FIG. 1, an emitter pad 104 is shown as the metal wiring.

As the semiconductor substrate 100, a silicon (Si) wafer such as a floating zone (FZ) wafer may be used, or a silicon carbide (SiC) wafer or the like may be used. For the interlayer insulating film 102, an insulating material such as silicon oxide may be used. For the metal wiring, a metal material such as aluminum is usually used.

A collector pad 106 is formed on the back surface of the semiconductor substrate 100. For the collector pad 106, a metal material such as aluminum is usually used.

On the back surface portion of the semiconductor substrate on the upper side of the collector pad 106, a P+ P-collector layer 110 having a high impurity concentration is formed, and an N+ field stop layer 112 having a higher impurity concentration than an N-drift layer 114 described later is formed thereon. These N-type and P-type regions in the semiconductor substrate 100 are formed by doping of impurities of respective types. The P-collector layer 110 functions as a collector region, and the field stop layer 112 prevents expansion of a depletion layer during OFF.

Note that, the impurity doping may be performed when a carrier store layer 116 is formed by epitaxial growth or the like, or the impurity may be doped into the semiconductor substrate 100 later.

The N-drift layer 114 configured by the N-type semiconductor substrate 100 is located on the field stop layer 112. The N-drift layer 114 is the body of the semiconductor substrate 100 and has a function as the base of a PNP bipolar transistor of the IGBT.

The N+ carrier store layer 116 having a higher impurity concentration than the N-drift layer 114 is arranged on the N-drift layer 114. The carrier store layer 116 has a function of accumulating holes to lower the on-resistance and lower the collector-emitter voltage (Vce), that is, the voltage drop, during ON.

A P− P-body layer 118 having a relatively low impurity concentration is arranged on the carrier store layer 116. The P-body layer 118 functions as an emitter of the PNP bipolar transistor.

In addition, a plurality of trenches 120 are formed downward from the front surface of the semiconductor substrate 100. The trenches 120 extend downward from the front surface of the semiconductor substrate 100 (the lower side of the interlayer insulating film 102), penetrate the P-body layer 118 and the carrier store layer 116, and reach the N-drift layer 114.

The trench 120 has a peripheral wall formed by an insulating film made of, for example, silicon oxide, so as to be insulated from the surroundings, and is filled with a conductive material, for example, polysilicon, in the interior. In this example, the trench 120 includes a trench-type main gate 120MG, the interior of which is connected to a main gate pad (not shown), and a trench-type control gate 120CG, the interior of which is connected to a control gate pad (not shown). In FIG. 1, the main gate 120MG, the control gate 120CG, a control unit 140 controlling the voltages thereof, and a wiring connecting them are schematically shown. The control unit 140 individually controls the voltages of the main gate 120MG and the control gate 120CG. That is, the control unit 140 turns on the control gate 120CG after turning on the main gate 120MG, and turns off the main gate 120MG after turning off the control gate 120CG.

The control unit 140 may be formed on the semiconductor substrate 100, or may be arranged separately. In addition, the control unit 140 may be configured by hardware or software as long as the control unit 140 generates and outputs a signal for turning on/off the main gate 120MG and the control gate 120CG from a signal for ON/OFF of the IGBT supplied from the outside. For example, control signals of the main gate 120MG and the control gate 120CG can be generated based on a control signal for ON/OFF of the IGBT.

In the embodiment, the IGBT is turned on in a case where the gate voltage is a positive voltage greater than or equal to a threshold voltage. For example, when the IGBT is to be turned on, the main gate 120MG and the control gate 120CG are set to +15 V, and when the IGBT is to be turned off, the main gate 120MG and the control gate 120CG are set to −15 V.

It is sufficient that the voltage can be switched to +15 V (ON) or −15 V (OFF) by the control unit 140 and then supplied to the main gate 120MG and the control gate 120CG.

In addition, an N+ emitter region 122 having a high impurity concentration is formed in an area that is on the front surface side of the P-body layer 118 and adjacent to the main gate 120MG and control gate 120CG. The emitter region 122 is electrically connected to the emitter pad 104. For example, in a portion not shown, the interlayer insulating film 102 is removed, and the emitter pad 104 and the emitter region 122 are directly connected.

Thereby, a region between the emitter region 122 and the carrier store layer 116 functions as a channel of a field effect transistor (FET), and when the FET is on, electrons, serving as carriers, flow from the emitter region to the N-drift layer 114 via the carrier store layer 116.

In addition, a contact 132 from the emitter pad 104 is arranged in a manner of extending to the P-body layer 118 of each mesa section formed between the plurality of trenches 120. Besides, the contact 132 is connected to a (P+) contact region 134 formed in the interior (in the middle portion) of the P-body layer 118 of the mesa section and having a high impurity concentration. Therefore, the emitter pad 104 is electrically connected to the contact 132 and the contact region 134, and holes accumulated in the N-drift layer 114 during turn-off can be extracted to the emitter pad 104 via the P-body layer 118.

In this way, in the embodiment, the emitter region 122 having a high impurity concentration is formed on the front surface portion of the semiconductor substrate 100, and the P-body layer 118 under the emitter region 122 functions as a channel.

Moreover, the gate regions in the interior of the main gate 120MG and the control gate 120CG are respectively connected to the main gate pad and the control gate pad arranged separately, and the insulating film of the peripheral wall of the trench 120 functions as a gate insulating film.

### “Operation of IGBT”

In a state where voltages are applied between the collector pad 106 and the emitter pad 104 (for example, 400 V to the collector pad 106 and 0 V to the emitter pad 104), a positive voltage (for example, +15 V) is applied to the main gate 120MG, and a positive voltage (for example, +15 V) is applied to the control gate 120CG after a predetermined time elapses. Note that, the above-described voltage of 400 V applied to the collector pad 106 is merely an example, and in some cases, the voltage applied may also be a low voltage such as a voltage of 10 V depending on the application target. Moreover, in this example, when IGBT is off, the main gate 120MG and the control gate 120CG are both set to −15 V.

When both the main gate 120MG and the control gate 120CG are turned on, an inversion layer is generated in a channel around these gates and the FET is turned on, and an electron current from the emitter region 122 toward the N-drift layer 114 flows. That is, with regard to the P region of the P-body layer 118, by setting the main gate 120MG and the control gate 120CG to a positive voltage, negative carriers (electrons) are accumulated on side walls of the main gate 120MG and the control gate 120CG, and by inverting the channel region thereof from P-type to N-type, a current flows here. Thereby, the PNP bipolar transistor is turned on, holes are supplied to the N-drift layer 114 from the collector side, and electrons are supplied from the emitter side, and thereby the IGBT is turned on. That is, by the movement of both the holes and the electrons, a current from the collector pad 106 toward the emitter pad 104 flows.

In addition, by the field stop layer 112, the expansion of the depletion layer can be suppressed, and thus the overall thickness can be reduced.

Here, in the IGBT of the embodiment, ON periods of the main gate 120MG and the control gate 120CG are made different.

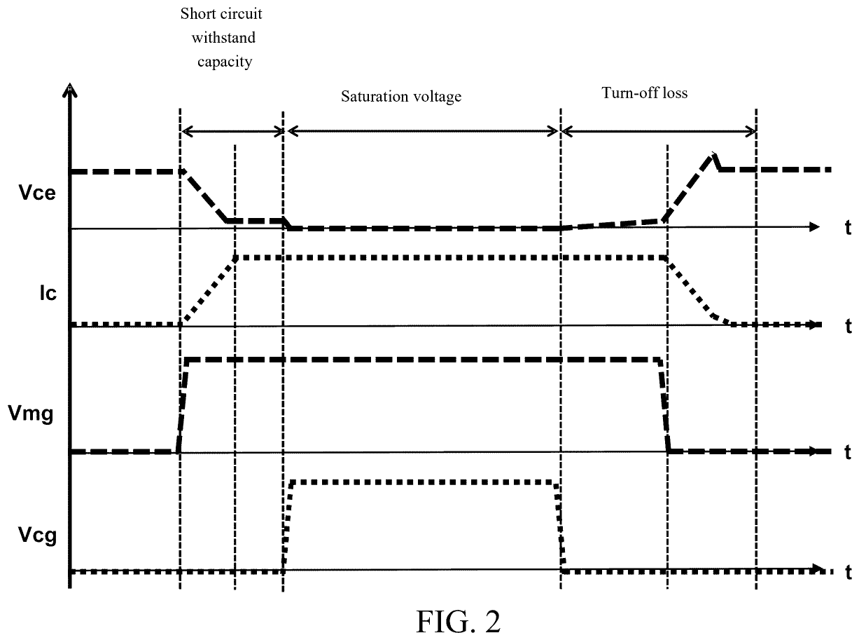

FIG. 2 is a timing chart showing states of the collector-emitter voltage Vce of the IGBT, the collector current Ic, the voltage Vmg of the main gate 120MG, and the voltage Vcg of the control gate 120CG when the IGBT is on for a predetermined time.

The voltage Vmg of the main gate 120MG is raised from a state in which the IGBT is off. Thereby, the FET with the main gate 120MG as the gate is turned on, and the corresponding PNP bipolar transistor is gradually turned on, and thereby the corresponding collector current Ic flows. In addition, as the PNP bipolar transistor is turned on, the collector-emitter voltage Vce gradually decreases.

Because only the voltage of the main gate 120MG is raised, the saturation current will not be large even if sufficient carriers (holes) are retained in the carrier store layer 116. Therefore, a desired short circuit withstand capacity can be satisfied by making the period during which only the main gate 120MG is on correspond to the period of short circuit withstand capacity. For example, in a case where the short circuit withstand capacity is set to 8 usec, the short circuit withstand capacity can be satisfied by setting the period during which only the main gate 120MG is on to 8 usec or more.

Next, the voltage Veg of the control gate 120CG is raised. Thereby, the FET with the control gate 120CG as the gate is also turned on, and more electron current flows. That is, by turning on the control gate 120CG, the number of channels increases, and by the increase of the electron current, the base current of the PNP transistor increases. Thereby, the on-resistance is reduced, and the Vce of the IGBT is further reduced. Therefore, the energy loss during ON can be reduced.

After a predetermined ON time, the voltage Veg of the control gate 120CG is lowered, and the FET with the control gate 120CG as the gate is turned off. Because the corresponding FET is kept on by the main gate 120MG, the current Ic continues flowing. Here, by the turn-off of the control gate 120CG, the injection amount of carriers decreases, and the amount of carriers in the interior decreases. Therefore, the voltage Veg gradually increases and becomes the same voltage as when only the main gate 120MG is turned on.

Next, the voltage Vmg of the main gate 120MG is lowered. Thereby, the FET with the main gate 120MG as the gate is also turned off, and the corresponding PNP bipolar transistor is gradually turned off, and thereby the corresponding collector current Ic decreases. In addition, as the PNP bipolar transistor is turned off, the collector-emitter voltage Vce gradually increases.

In this way, according to the embodiment, when the IGBT is to be turned on, first only the main gate 120MG is turned on, and the control gate 120CG is also turned on after a predetermined time elapses. Therefore, the desired short circuit withstand capacity can be obtained in a period during which only the main gate 120MG is on. In addition, when the IGBT is to be turned off, first only the control gate 120CG is turned off. Thereby, carriers in the FET corresponding to the control gate 120CG are removed, and carriers remaining in the N-drift layer 114 and the P-body layer 118 can be extracted to the emitter pad 104.

When the main gate 120MG is turned off, the amounts of carriers in the N-drift layer 114, the carrier store layer 116, and the P-body layer 118 are reduced. Therefore, the main gate 120MG is set to a negative voltage (for example, −15 V), and when the IGBT is turned off, the carriers can be eliminated in a relatively short time. Therefore, the loss during turn-off can be reduced.

Next, a comparison result between the IGBT of the embodiment of FIG. 1 and an IGBT of a comparative example is described. Here, in the configuration of the embodiment of FIG. 1, five control gates 120CG are lined up for one main gate 120MG, while in the configuration of the comparative example, three control gates 120CG are lined up for two main gates 120MG. In addition, the control gate 120CG of the embodiment is set to +15 V during ON and −15 V during OFF, while the control gate 120CG of the comparative example is set to 0 V during ON and 0 V during OFF, that is, 0 V at all times. Therefore, in the comparative example, no FET is formed and the emitter region is also omitted in the region in which the control gate 120CG is arranged.

In addition, the carrier addition amount is the amount of impurities doped into the carrier store layer 116 by implantation, and is expressed in units of (atoms/cm²).

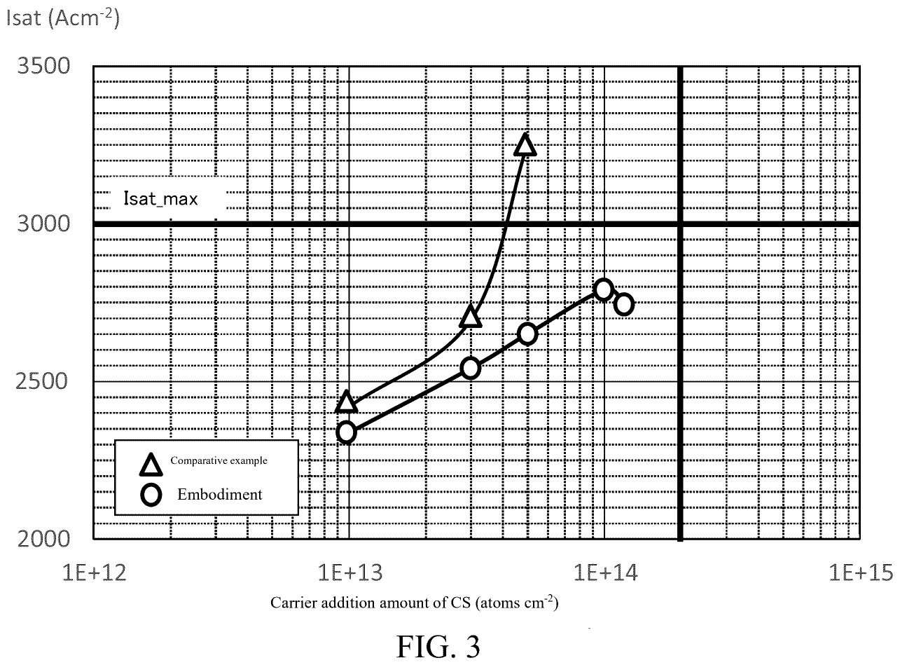

FIG. 3 is a diagram showing the relationship between the carrier addition amount (atoms/cm²) of the carrier store (CS) layer and the saturation current Isat (A/cm²). The embodiment of FIG. 1 and the comparative example are shown.

As shown in FIG. 3, in the IGBT of the comparative example, by increasing the carrier concentration of the carrier store layer 116, the saturation current increases. On the other hand, in the IGBT of the embodiment, by providing a period during which only the main gate 120MG is on, the ON area can be limited, and the increase of the saturation current can be suppressed.

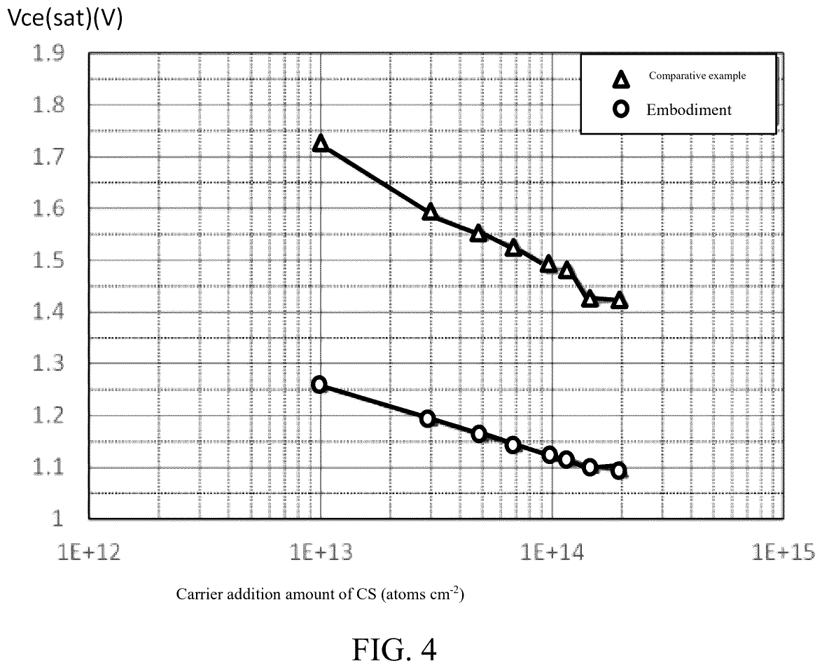

FIG. 4 is a diagram showing the relationship between the carrier addition amount (atoms/cm²) of the carrier store (CS) layer 116 and the collector-emitter saturation voltage Vce(sat) (V). As shown in FIG. 4, it can be seen that the saturation voltage decreases in the IGBT of the embodiment. That is, in the embodiment, by turning on both the main gate 120MG and the control gate 120CG, the base current of the PNP bipolar transistor can be increased, so that the on-resistance of the IGBT is small, and thus the loss during ON can be reduced.

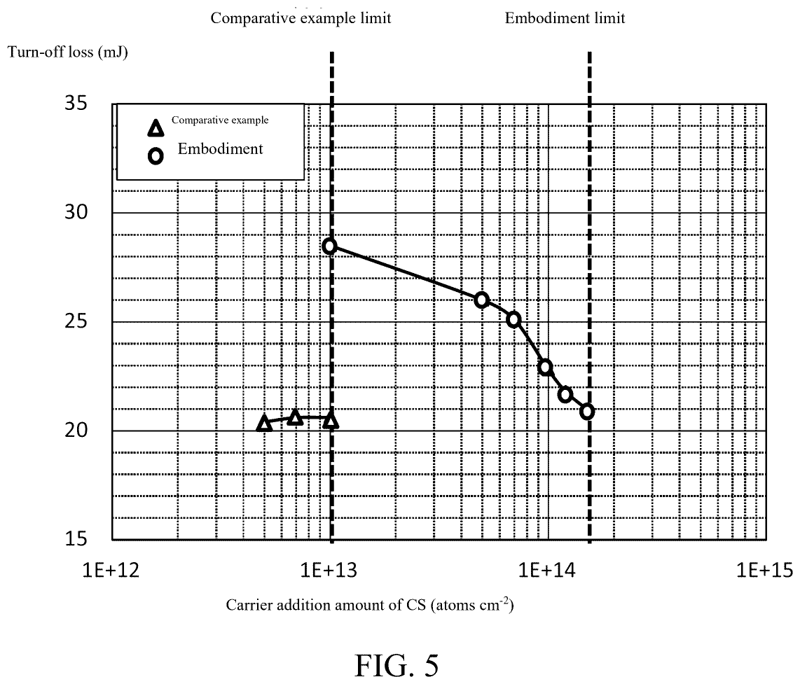

FIG. 5 is a diagram showing the relationship between the carrier addition amount of the carrier store (CS) layer 116 (atoms/cm²) and the loss during turn-off (mJ). As shown in FIG. 5, in the comparative example, it is unable to increase the carrier addition amount to increase the saturation current and achieve the desired short circuit withstand capacity. In addition, because the control gate 120CG is not turned on, the amount of remaining carriers (holes) during OFF is relatively small, and the turn-off loss is relatively small. On the other hand, in the IGBT of the embodiment, because both the main gate 120MG and the control gate 120CG are turned on, the loss during OFF at the same carrier concentration as in the comparative example is relatively high. This is because by turning off the control gate 120CG earlier than the main gate 120MG, the carriers of the drift layer decreases earlier than in the comparative example, and thus the conductivity modulation is weakened and the collector-emitter saturation voltage (Vce(sat)) increases. However, although by further increasing the carrier concentration, the collector-emitter saturation voltage (Vce(sat)) during ON can be reduced, and more carriers than in the comparative example are accumulated in the carrier store layer, by turning off the control gate 120CG first, the carrier in the area can be consumed, and thus the loss during turn-on can be reduced.

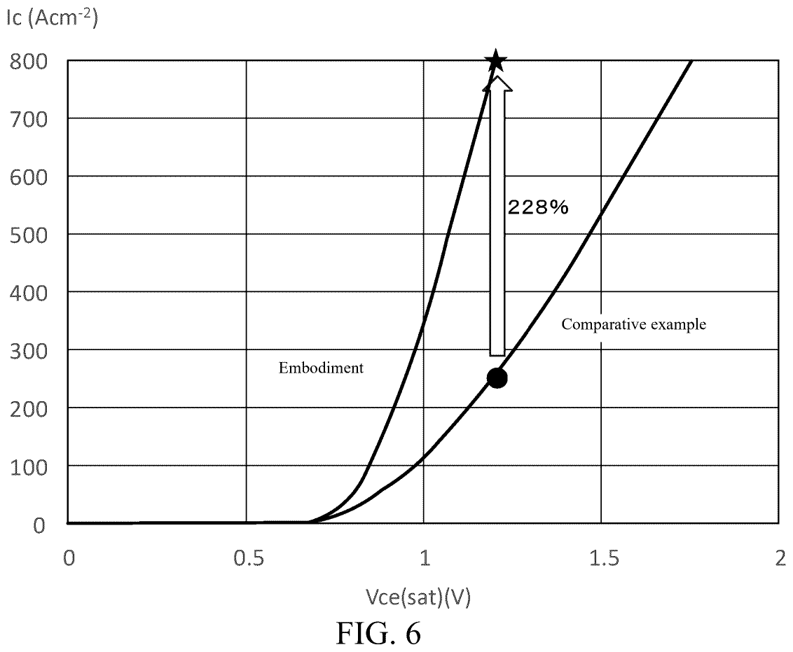

FIG. 6 is a diagram showing the relationship between the collector-emitter saturation voltage (Vce(sat)) and the collector current Ic. As shown in FIG. 6, the collector current Ic can be made larger in the embodiment than in the comparative example. In a case where the collector-emitter saturation voltage Vce(sat) is 1.2 V, the current can be increased by 228% in the embodiment. Therefore, by the embodiment, the chip size can be reduced by approximately 70%.

### “Planar Configuration and Cross-Sectional Configuration”

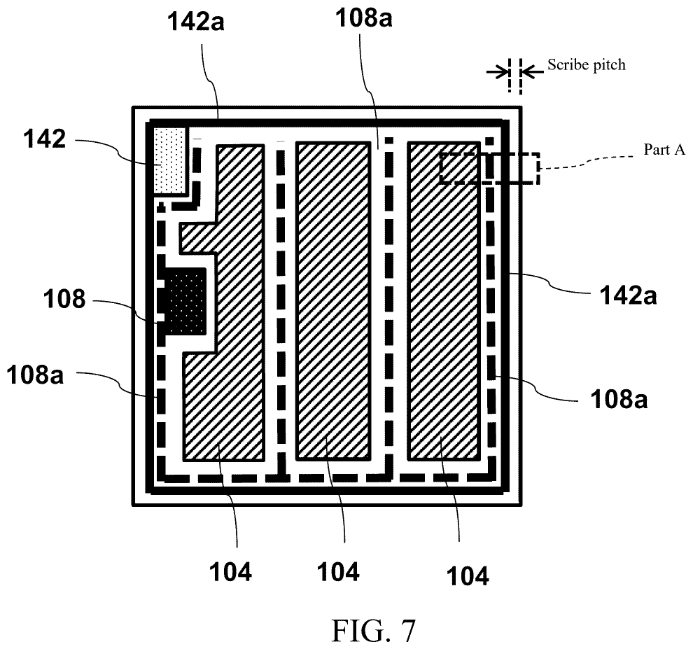

FIG. 7 is a plan view showing an example of a metal wiring layer (single-layer) of the IGBT. In this example, the IGBT has a square planar shape.

The emitter pad 104 divided into three parts in the longitudinal direction in the figure is arranged in the square front surface. The three emitter pads 104 are spaced apart from the peripheral portion, and predetermined gaps are arranged between the three emitter pads 104.

The upper left corner of the emitter pad 104 on the left side in the figure is recessed, and a control gate pad 142 is arranged at this upper left corner. In addition, a rectangular control gate wiring 142a is arranged in connection to the control gate pad 142 and along the outer periphery of the front surface of the IGBT. The control gate wiring 142a is arranged on the inner side at a scribe pitch from the outer periphery. The control gate pad 142 functions as a control constant terminal that controls the voltage of the control gate 120CG.

In addition, the left side center of the left emitter pad 104 is recessed, and a main gate pad 108 is arranged here. A main gate wiring 108a is connected to the main gate pad 108, and the main gate wiring 108a extends to both left and right sides, to the lower side, and to the longitudinal gaps of the three emitter pads 104.

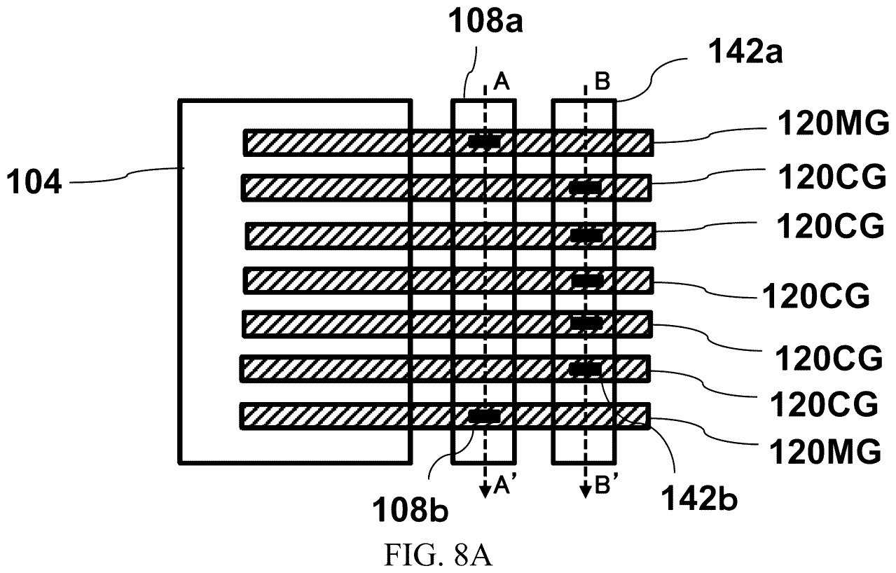

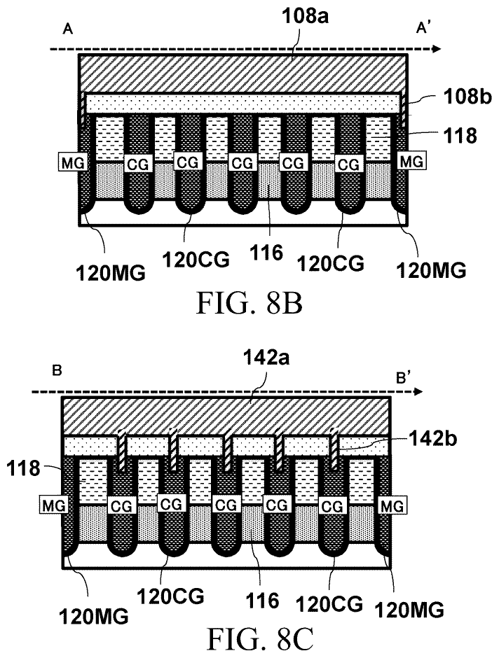

FIG. 8A is an enlarged schematic diagram of part A in FIG. 7, and also shows a structure in the semiconductor substrate 100. FIG. 8B is a cross-sectional view taken along line A-A′ of FIG. 8A, and FIG. 8C is a cross-sectional view taken along line B-B′ of FIG. 8A.

As shown in FIGS. 8A to 8C, the main gate 120MG and the control gate 120CG extend in the horizontal direction, and are located below the emitter pad 104, the main gate wiring 108a, and the control gate wiring 142a, which extend in the longitudinal direction.

Besides, the main gate 120MG and the main gate wiring 108a are connected by a contact 108b extending downward, and the control gate 120CG and the control gate wiring 142a are connected by a contact 142b extending downward.

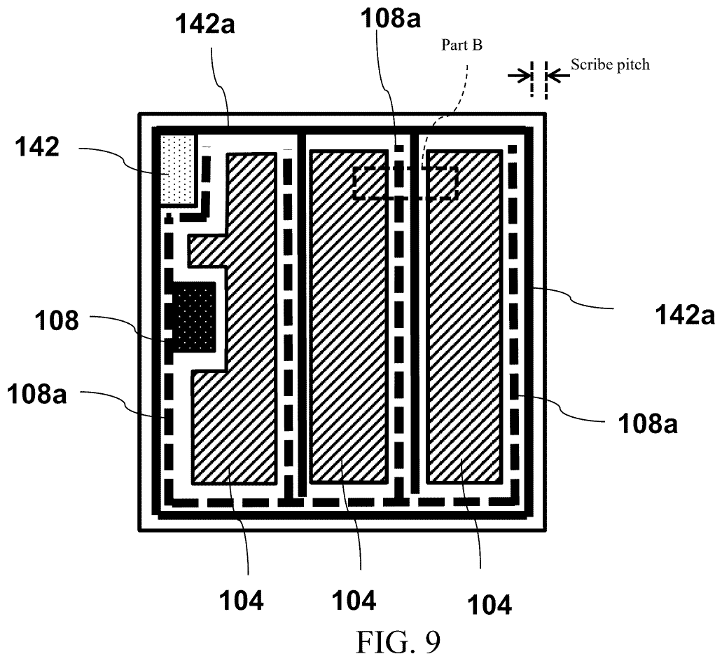

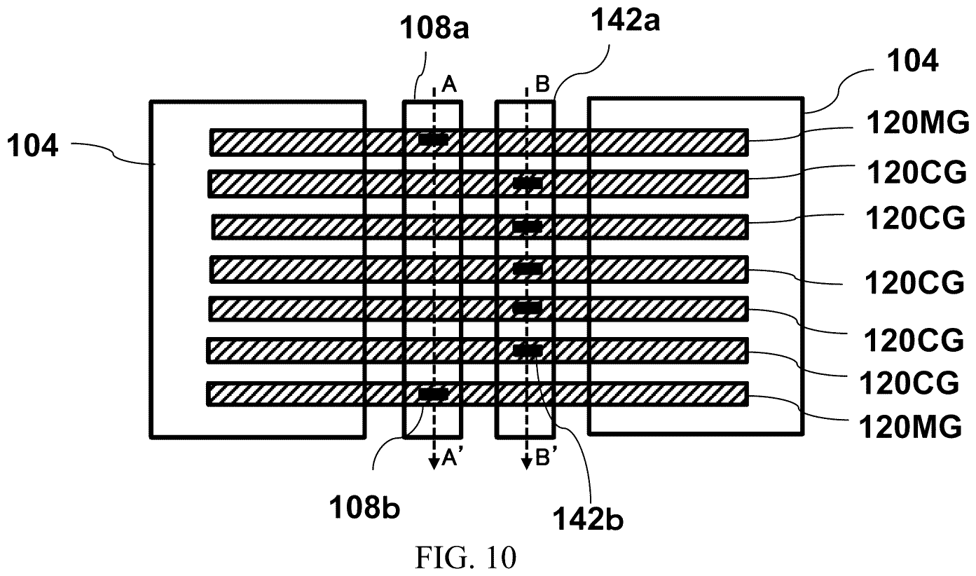

FIG. 9 is a plan view showing another example of the metal wiring layer (single-layer) of the IGBT. In addition, FIG. 10 is an enlarged view of part B of FIG. 9.

In this example, the control gate wiring 142a also extends into the gaps of the divided emitter pad 104. Therefore, the number of contacts 142b between the control gate wiring 142a and the control gate 120CG can be increased, and an electric field generated by the control gate 120CG can be set in advance.

Note that, a cross-sectional view taken along line A-A′ and a cross-sectional view taken along line B-B′ of FIG. 10 are respectively the same as FIG. 8B and FIG. 8C. In addition, various arrangements different from the above example can also be used as long as it is an arrangement in which the main gate wiring 108a and the control gate wiring 142a do not interfere with each other.

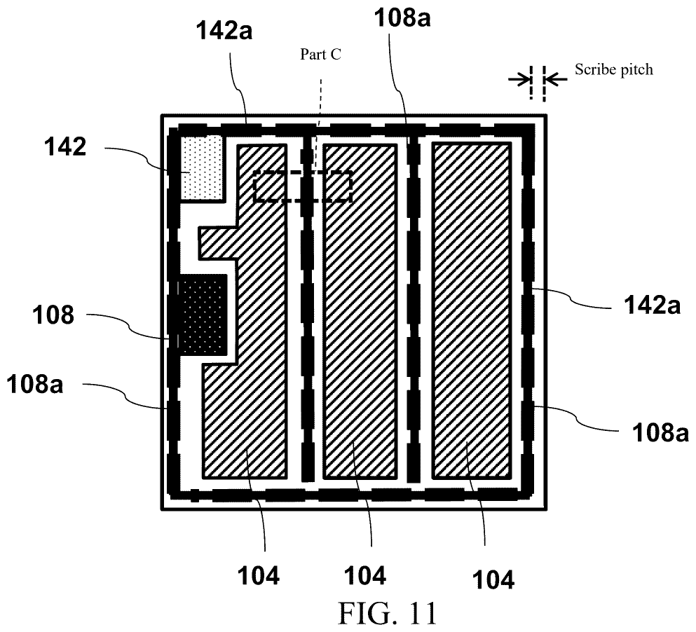

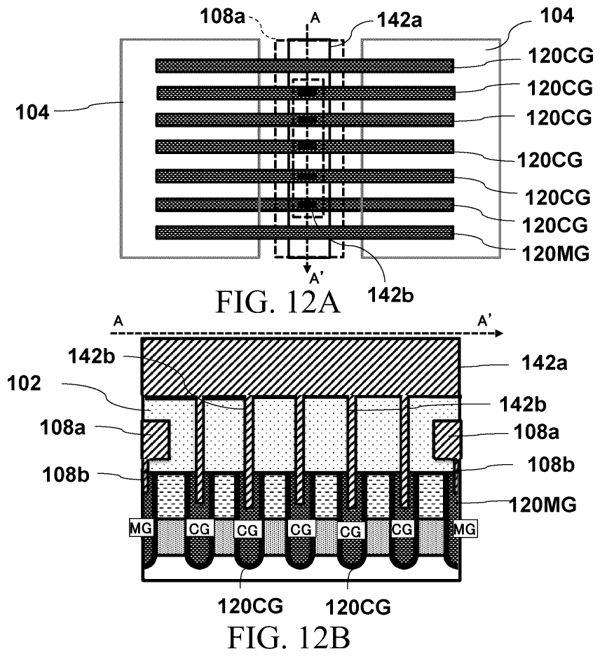

FIG. 11 is a plan view showing an example of the metal wiring layer (two-layer) of the IGBT. In addition, FIG. 12A is an enlarged view of part C of FIG. 11, and FIG. 12B is a cross-sectional view taken along line A-A′ of FIG. 12A.

As shown in FIG. 11, on the front surface of the semiconductor substrate 100, the emitter pad 104, the main gate pad 108, the control gate pad 142, and the control gate wiring 142a are present, but the main gate wiring 108a is not present. As shown in FIG. 12B, the main gate wiring 108a is arranged in the interlayer insulating film 102 under the control gate wiring 142a. Moreover, in FIG. 11, the main gate wiring 108a is schematically shown using a dashed line in a manner of being slightly shifted in position. Because the control gate wiring 142a and the main gate wiring 108a are at different positions in the thickness direction, there is no problem even if the control gate wiring 142a and the main gate wiring 108a overlap in the plan view. In addition, the main gate wiring 108a doesn't have to come into contact with the contact 142b, and in FIG. 12A, the main gate wiring 108a is removed for the area where the contact 142b is arranged. In this way, by making the wiring layer into a two-layer structure, the area for arranging a plurality of wirings can be reduced.

### <Another Configuration Example of IGBT>

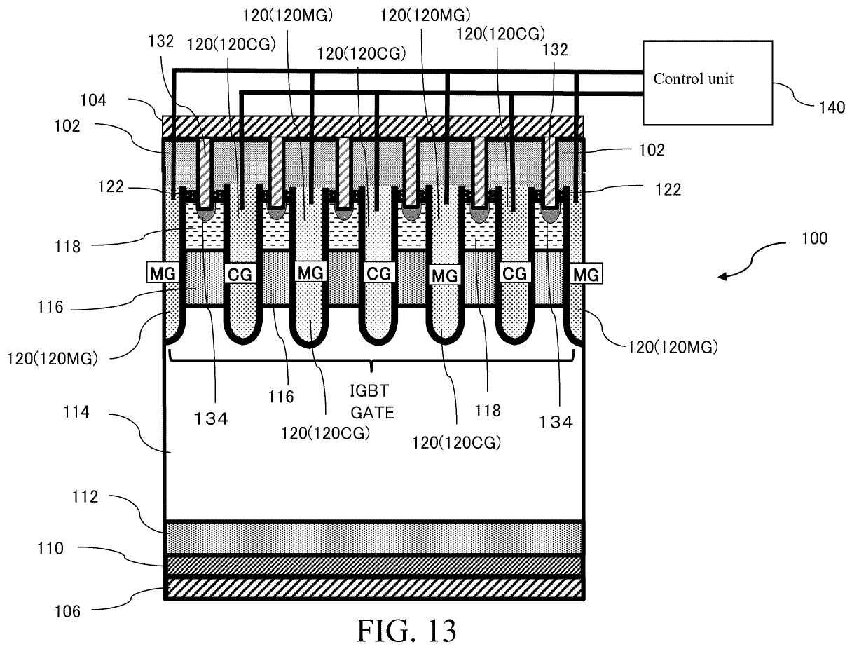

FIG. 13 is a cross-sectional view schematically showing another configuration example of the trench gate type IGBT. In this example, the main gate 120MG and the control gate 120CG are alternately arranged. Even in such a configuration, similarly, the main gate 120MG is turned on first and then the control gate 120CG is turned on, and the main gate 120MG is turned off after the control gate 120CG is turned off, and thereby the same effect as in the above embodiment can be obtained.

### <Configuration Example of Control Unit>

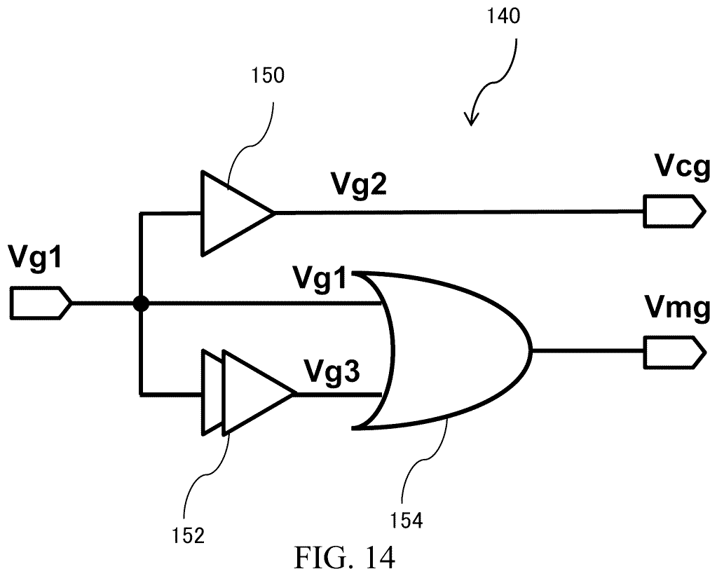

FIG. 14 is a diagram showing a configuration example of the control unit 140.

A control signal Vg1 for ON/OFF of the IGBT is provided from the outside. The control signal Vg1 becomes a signal Vg2 delayed for a predetermined time by a first delay circuit 150. The signal Vg2 is supplied to the control gate 120CG and becomes the voltage Veg of the control gate 120CG.

The signal Vg1 is directly input to a first input end of an OR gate 154. In addition, the signal Vg1 is delayed by a second delay circuit 152 and becomes a signal Vg3. The delay time of the second delay circuit 152 is longer than the delay time of the first delay circuit 150. The Vg3, which is an output of the second delay circuit 152, is input to a second input end of the OR gate 154. The output of the OR gate 154 is supplied to the main gate 120MG and becomes the voltage Vmg of the main gate 120MG.

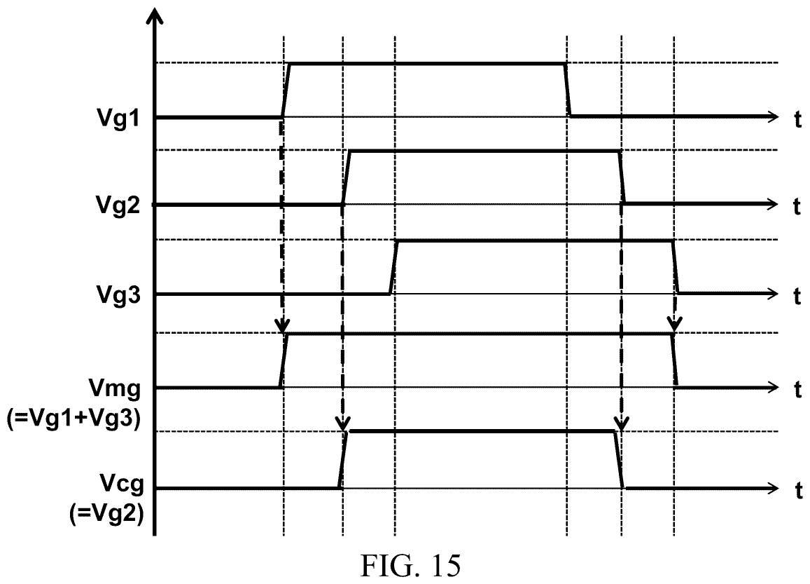

FIG. 15 is a timing chart describing operations of the control unit 140. As shown in FIG. 15, the signal Vg2 is delayed for a predetermined time relative to the signal Vg1, and the signal Vg3 is significantly delayed relative to the signal Vg1 than the signal Vg2.

A signal which is the output of the OR gate 154 (=the voltage Vmg of the main gate 120MG) rises by the rise of the signal Vg1 and falls by the fall of the signal Vg3. Therefore, first the voltage Vmg of the main gate 120MG rises and then the voltage Veg of the control gate 120CG rises, and after a predetermined time elapses, the voltage Vcg of the control gate 120CG falls, and then the voltage Vmg of the main gate 120MG falls.

### [Manufacturing Process]

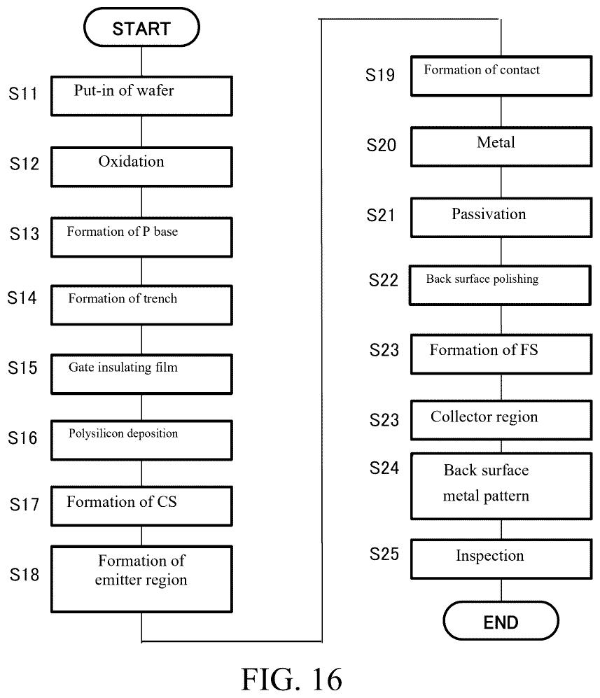

FIG. 16 is a diagram showing a manufacturing process of the IGBT according to the embodiment. First, the semiconductor substrate 100 is prepared and put into the manufacturing process (S11). As the semiconductor substrate 100, for example, an N-type floating zone (FZ) wafer is used.

First, the front surface side is oxidized to form the interlayer insulating film 102 (S12). Note that, in order to produce a plurality of elements (IGBTs in this case) on one wafer, element separation processing may be performed at this stage.

Next, the P+P-body layer 118 is formed by doping P-type impurities from the front surface side (S13). The trench is formed by etching from the front surface side (S14), and an oxide film is formed on the wall surface of the formed trench (S15). In a case where the trench is a gate trench, the oxide film becomes a gate insulating film. Then, polysilicon is deposited in the interior of the trench (S16). The polysilicon is conductive, and the interior of the trench becomes a gate region.

Then, the carrier store layer (CS layer) 116 is formed by injection of N-type impurities (S17). Then, the emitter region is formed by injection of N-type impurities from the front surface side (S18).

Contact holes are formed by etching from the front surface side, and the contact region 134 is formed by injection of P-type impurities. Next, after the interlayer insulating film 102 is formed, necessary contact holes are formed. Then, the emitter pad 104, the main gate pad 108, the control gate pad 142, the contacts extending inside the contact holes, and the like are formed by metal deposition (S20). Then, the front surface side is covered by a passivation film (S21).

Next, the back surface side is polished (S22), and the field stop layer 112 and the P-collector layer 110 are sequentially formed from the back surface side (S23). Then, the collector pad 106 is formed by metal deposition (S24).

In this way, the IGBT is formed, then various inspections are performed on the formed IGBT (S25), and the manufacturing process is completed.

### DESCRIPTION OF THE REFERENCE NUMERALS

100: semiconductor substrate
102: interlayer insulating film
104: emitter pad
106: collector pad
108: main gate pad
108a: main gate wiring
110: P-collector layer
112: field stop layer
114: N-drift layer
116: carrier store layer
118: P-body layer
120: trench
120MG: main gate
120CG: control gate
122: emitter region
132: contact
134: contact region
140: control unit
142: control gate pad
142a: control gate wiring
142b: contact

What is claimed is:

1. A trench gate type IGBT, comprising:
a semiconductor substrate; and
a plurality of trench-type gates, extending from the front surface of the semiconductor substrate to the back surface side and controlling a current flowing, by application of a voltage, to a channel region formed in the periphery; the trench gate type IGBT controlling a current between an emitter and a collector by the voltage applied to the trench-type gates; wherein
the plurality of trench-type gates comprise:
one or more main gates, which have a relatively long ON time; and
one or more control gates, which have a relatively short ON time, are turned on after the main gates are turned on, and are turned off before the main gates are turned off.

2. The trench gate type IGBT according to claim 1, wherein
the number of the one or more main gates is two or more, and
the one or more control gates are arranged between two of the main gates.

3. The trench gate type IGBT according to claim 1, wherein
the number of the one or more control gates is two or more, and
two or more control gates are arranged between two main gates.

4. A trench gate type IGBT, comprising:
a semiconductor substrate;
an emitter pad, formed on the front surface of the semiconductor substrate;
a collector pad, formed on the back surface of the semiconductor substrate;
a P-type P-collector layer, formed on the back surface side of the semiconductor substrate on the collector pad;
an N-type N-drift layer, located on the P-collector layer in the semiconductor substrate;
an N-type carrier store layer, formed on the N-drift layer and having a higher impurity concentration than the N-drift layer;
a P-type P-body layer, formed on the front surface side of the carrier store layer of the semiconductor substrate;
a plurality of main gates, which are a plurality of trench-type main gates formed discretely from the front surface side of the semiconductor substrate with mesa sections interposed therebetween and extending toward the back surface side to the N-drift layer, and have a gate region formed in the interior with an insulating film therebetween;
a control gate, which is a trench-type control gate formed discretely from the front surface side of the semiconductor substrate with mesa sections interposed therebetween and extending toward the back surface side to the N-drift layer, and has a gate region formed in the interior with an insulating film therebetween;
a main gate pad, formed on the front surface of the semiconductor substrate and connected to the main gate; and
a control gate pad, formed on the front surface of the semiconductor substrate and connected to the control gate; wherein
an ON time of the main gate is longer than an ON time of the control gate, and the control gate is turned on after the main gate is turned on, and is turned off after the main gate is turned off.

5. The trench gate type IGBT according to claim 4, wherein
the number of the one or more main gates is two or more, and
the one or more control gates are arranged between two of the main gates.

6. The trench gate type IGBT according to claim 4, wherein
the number of the one or more control gates is two or more, and
two or more control gates are arranged between two main gates.

7. The trench gate type IGBT according to claim 4, wherein
the impurity concentration of the carrier store layer is 3E¹⁷ to 2E¹⁸ (atoms/cm²).

8. A driving method of trench gate type IGBT,
the trench gate type IGBT comprising:
a semiconductor substrate; and
a plurality of trench-type gates, which extend from the front surface of the semiconductor substrate to the back surface side, and by which a current is made to flow, by application of a voltage, to a channel region formed in the periphery; wherein
at least one of the plurality of trench-type gates is a main gate and the main gate is on for a relatively long time; and
at least one of the plurality of trench-type gates is a control gate, and the control gate is turned on after the main gate is turned on, and is turned off before the main gate is turned off.

9. The driving method of trench gate type IGBT according to claim 8, wherein
the number of the one or more main gates is two or more, and
the one or more control gates are arranged between two of the main gates.

10. The driving method of trench gate type IGBT according to claim 8, wherein
the number of the one or more control gates is two or more, and
two or more control gates are arranged between two main gates.
